(19) United States
(12) Patent Application Publication
(10) Pub. No.: US 2006/0119367 A1
(43) Pub. Date: Jun. 8, 2006

(54) Apparatus for Inspecting the front side and backside of a disk-shaped object

(75) Inventors: Thomas Iffland, Jena (DE); Rene Schenck, Jena (DE)

Correspondence Address: HOUSTON ELISEEVA, 4 MILITIA DRIVE, SUITE 4, LEXINGTON, MA, 02421, US

(73) Assignee: Leica Microsystems Jena GmbH, Jena (DE)

(21) Appl. No.: 11/289,032

(22) Filed: Nov. 29, 2005

(30) Foreign Application Priority Data
Dec. 2, 2004 (DE) DE 102004058126.6

(51) Int. Cl. G01R 31/00; C23C 16/00

(52) U.S. Cl. 324/500; 118/719

(57) ABSTRACT

An apparatus for inspecting the front side and the back side 2, 3 of a disc-shaped object 4 is disclosed. A detection unit 5 has a first detector element 6 facing the front side 2 and a second detector element 7 facing the back side of the disc-shaped object 4. Furthermore, a means 8 is provided for generating a relative movement between the detection unit 5 and the disc-shaped object 4 so that an image is made of the front side and the back side 2, 3 of the disc-shaped object 4.

### RELATED APPLICATIONS

This application claims priority to German patent application number DE 10 2004 058 126.6, filed Dec. 2, 2004, which is incorporated herein by reference in its entirety.

### FIELD OF INVENTION

The invention relates to an apparatus for inspecting the front side and back side of a semiconductor substrate.

### BACKGROUND OF THE INVENTION

In semiconductor manufacture, wafers are processed sequentially in a multiplicity of processing steps during the production process. The quality requirements for structures applied to the wafers increase with increasing integration density. As a result, the need to test for defects, not only on the front side of the wafer, but to find defects on the back side of the wafer as well, increases. The front side of the wafer is the side to which the various structures are applied.

U.S. Pat. No. 6,559,938 B1 discloses a device for simultaneously inspecting for defects on the front side and the back side of a wafer. The wafer lies on a table that exhibits an open channel that in its length corresponds to the diameter of the wafer. A detector moves in the channel and therefore takes an image of a part of the wafer. In order to image the entire surface of the wafer, the wafer can be rotated on the table. The friction between the table and the wafer is minimized by corresponding air bearings. Simultaneous imaging or inspection of the entire surface of the front side and the back side of the wafer is not possible with this apparatus.

U.S. Pat. No. 6,747,464 B1 discloses a wafer holder with which the back side of the wafer can be observed and measurements can be taken on the front side of the wafer. The wafer holder may be used in machines for automatically inspecting a wafer. The wafer holder is implemented such that the front side and the back side of the wafer are almost completely accessible from both sides. Simultaneous imaging of the front side and the back side of the wafer is not possible with the wafer holder.

US patent application 2004/0087146 discloses a ring-shaped wafer holder. The wafer holder possesses a bracket for the wafer and is open at the top so that the wafer can be completely inspected from one side. The wafer rests with its other side on a crib that is implemented with an inspection window through which a fraction of the side of the wafer that lies on the crib can be inspected. Simultaneous and complete inspection of the front side and the back side of the wafer is not possible with this wafer holder.

German published application DE 101 21 115 A1 discloses a holding apparatus for a wafer. The holding apparatus possesses two grippers that in their closed state surround the edge of the wafer. The front side and back side of the wafer are therefore not covered. The holding apparatus can be swiveled, which enables visual inspection of the back side of the wafer.

German published application DE 103 07 373 A1 discloses a method and an apparatus for inspecting semiconductor wafers, taking die-saw designs into consideration. An image of the entire wafer can be constructed from a multiplicity of individual images. In the process, the size of the image field of the camera is selected such that the current die/saw design is taken into account.

### SUMMARY OF THE INVENTION

The object underlying the invention is to create an apparatus with which it is possible to inspect or image both the front side and the back side of a disc-shaped object simultaneously.

This object is solved by an apparatus for inspecting the front side and the back side of a disc-shaped object, which exhibits a detection unit with a first detector element facing the front side and a second detector element facing the back side of the disc-shaped object, and in which a means is provided for generating a relative movement between the detection unit and the disc-shaped object so that an image is made of the front side and the back side of the disc-shaped object.

It is particularly advantageous that the apparatus for inspecting the front side and back side of a disc-shaped object comprise a detection unit. The detection unit has a first detector element facing the front side of the disc-shaped object and a second detector element facing the back side of the disc-shaped object. A means is provided for generating a relative movement between the detection unit and the disc-shaped object so that an image is made of the front side and the back side of the disc-shaped object.

The disc-shaped object may be a wafer on a semiconductor substrate, or on a glass substrate, or a mask for lithography, or a flat-panel display.

An edge grip system is provided that fixes the disc-shaped object in place. The first and the second detector element is a linear detector with integrated optic and an integrated light.

The means for generating a relative movement between the detection unit and the disc-shaped object is a movement device, whereby the first and a second detector element are attached to the movement device, which moves the first and the second detector element along the top and bottom of the disc-shaped object when the disc-shaped object is fixed in place.

The first and the second detector element is a linear detector with an integrated optic, whereby an external light is provided for the two-dimensional object. The light is fixed in place and glances across the wafer.

The first and the second detector element have at least the same width as the two-dimensional object.

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention.

In the diagram, the subject of the invention is schematically represented and described below based on the figures. They show:

FIG. 1 a schematic top view of the construction of the apparatus for simultaneous inspection of the front side and the back side of a disc-shaped object;

FIG. 2 a schematic lateral view of the construction of the apparatus for simultaneous inspection of the front side and the back side of the disc shaped object;

FIG. 3 a top view of a first embodiment of a detector element for the detection unit;

FIG. 4 a top view of a second embodiment of a detector element for the detection unit;

FIG. 5 a lateral view of the linear detector; and

FIG. 6 a lateral view of a further embodiment of the construction of the apparatus for simultaneous inspection of the front side and the back side of the disc shaped object, whereby the light is provided externally.

### DETAILED DESCRIPTION OF THE PREFERRED EMBODIMENTS

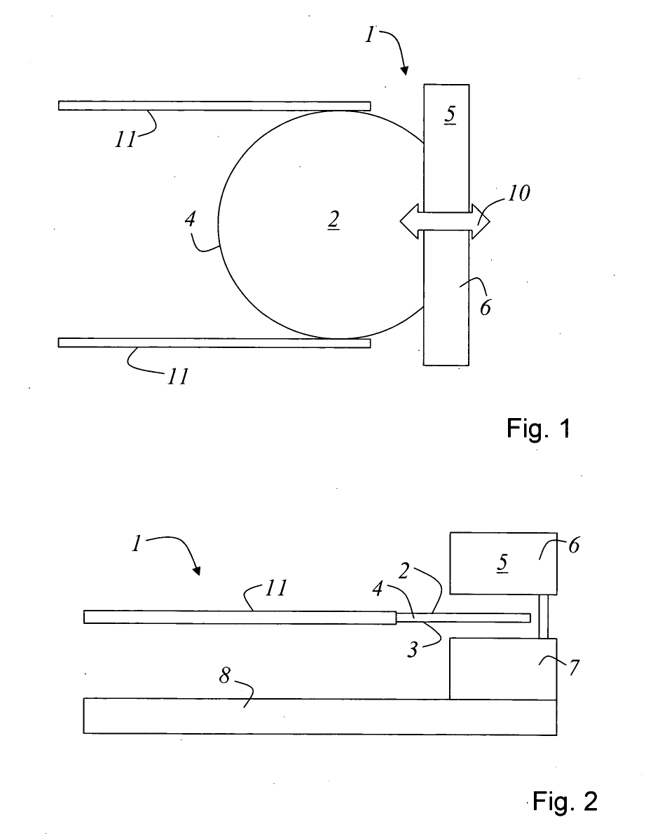

FIG. 1 shows a schematic top view of the construction of an apparatus 1 for simultaneous inspection of the front side and the back side 2, 3 (see FIG. 2) of a disc-shaped object 4. FIG. 2 represents a lateral view of the construction of the apparatus for simultaneous inspection of the front side and the back side 2, 3 of the disc-shaped object 4. It is obvious that the same reference numbers in the different figures relate to the same characteristics of the invention. The apparatus 1 comprises a detection unit 5. The detection unit 5 comprises a detector element 6 facing the front side and a detector element 7 facing the back side of the disc-shaped object 4. Furthermore, a means 8 is provided for generating a relative movement between the detection unit 5 and the disc-shaped object 4. As a result, the detection unit 5 (first detector element 6 and second detector element 7) creates an image of the front side and the back side 2, 3 of the disc-shaped object 4. The direction of the relative movement is shown in FIG. 1 with a double arrow 10. The disc-shaped object 4 can be a wafer on a semiconductor substrate, or a wafer on a glass substrate, or a mask for lithography, or a flat-panel display. A crib is provided that fixes in place the disc-shaped object 4. The edge grip system 11 makes the front side and the back side of the disc-shaped object 4 accessible for optical inspection. The first detector element 6 and the second detector element 7 are at least as wide as the disc-shaped object 4. The means 8 for generating the relative movement between the detection unit 5 and the disc-shaped object 4 is a movement device that can, for example, be implemented as a carriage. The first detector element 6 and the second detector element 7 are attached to the movement device. As a result of the movement device, the first detector element 6 and a second detector element 7 may be moved simultaneously along the top and bottom of disc-shaped object 4 when the disc-shaped object 4 is fixed in place.

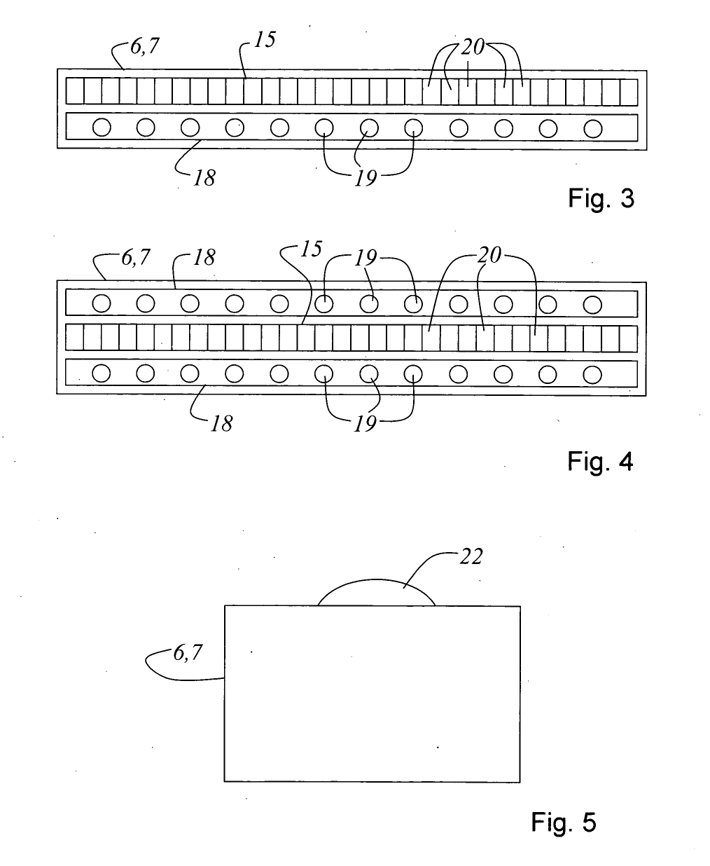

FIG. 3 is a top view of a first embodiment of a detector element 6, 7 for the detection unit 5. The detector element 6, 7 has a largely linear form. In the embodiment represented here, the detector element 6, 7 comprises at least one linear arrangement 15 of individual detectors 20. The detector element 6, 7 is also provided with a light that is arranged parallel to the linear arrangement. The light 18 may consist of an array of several diodes 19. A suitably dimensioned surface emitter is also conceivable as the light 18.

FIG. 4 shows a top view of second embodiment of a detector element 6, 7 for the detection unit 5. The detector element 6, 7 has a largely linear form. In the embodiment represented here, the detector element 6, 7 comprises at least one linear arrangement 15 of individual detectors 20. The detector element 6, 7 is also provided with a light that is arranged parallel to the linear arrangement. The light 18 may consist of an array of several diodes 19. A suitably dimensioned surface emitter is also conceivable as the light 18.

FIG. 5 shows a lateral view of the detector element 6, 7. Here the first and the second detector element 6, 7 comprise a linear arrangement 15 of detectors 20 having at least one integrated optic 21 for imaging the front side and the back side 2, 3 of a disc-shaped object 4. Furthermore, as already described in FIGS. 3 and 4, the first and the second detector element 6, 7 may be implemented with an integrated light 18.

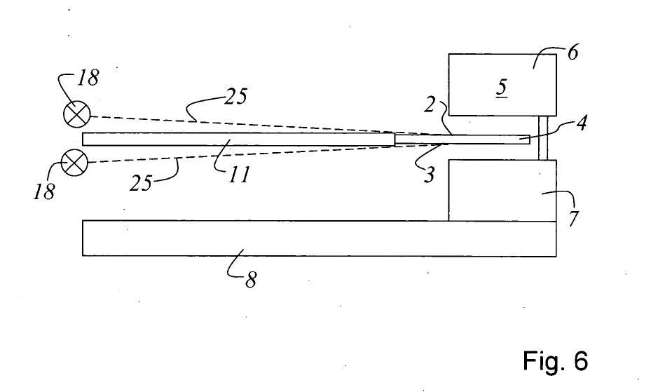

FIG. 6 shows a lateral view of a further embodiment of the construction of the apparatus for simultaneous inspection of the front side and back side 2, 3 of a disc-shaped object 4, whereby the light 18 is provided externally. The light 18 is fixed in place and emits a two-dimensional light beam 25 that glances across the front side and the back side 2, 3 of the disc-shaped object 4.

While this invention has been particularly shown and described with references to preferred embodiments thereof, it will be understood by those skilled in the art that various changes in form and details may be made therein without departing from the scope of the invention encompassed by the appended claims.

What is claimed is:

1. An apparatus for inspecting the front side and the back side of a disc-shaped object, comprising a detection unit that exhibits a first detector element facing the front side and a second detector element facing the back side of the disc-shaped object, and wherein a means is provided for generating a relative movement between the detection unit and the disc-shaped object so that an image is made of the front side and the back side of the disc-shaped object.

2. Apparatus according to claim 1, wherein the disc-shaped object is a wafer on a semiconductor substrate.

3. Apparatus according to claim 1, wherein the disc-shaped object is a wafer on a glass substrate.

4. Apparatus according to claim 1, wherein the disc-shaped object is a mask for lithography.

5. Apparatus according to claim 1, wherein the disc-shaped object is a flat-panel display.

6. Apparatus according to one of claim 1, wherein an edge grip system is provided that fixes in place the disc-shaped object.

7. Apparatus according to claim 1, wherein the first and the second detector element is a linear detector with an integrated optic and an integrated light.

8. Apparatus according to claim 1, wherein a the means for generating the relative movement between the detection unit and the disc-shaped object is a movement device, whereby the first and the second detector element are attached to the movement device that moves the first and the second detector element along the top and bottom of the disc-shaped object when the disc-shaped object is fixed in place.

9. Apparatus according to claim 1, wherein the first and second detector element comprise a linear detector with an integrated optic, and that an external fixed light is provided for the two-dimensional object.

10. Apparatus according to claim 9, wherein the first and the second detector element are attached to a movement device that moves the first and the second detector element above and below the two-dimensional object.

11. Apparatus according to claim 7, wherein the light is fixed in place and glances across the two-dimensional object.

12. Apparatus according to claim 1, wherein the first and the second detector element exhibit at least the width of the two-dimensional object.
